(19) United States
(12) Patent Application Publication
(10) Pub. No.: US 2019/0131459 A1
(43) Pub. Date: May 2, 2019

(54) THIN FILM TRANSISTOR

(71) Applicant: Sharp Kabushiki Kaisha, Sakai City, Osaka (JP)

(72) Inventors: Tadayoshi MIYAMOTO, Sakai City (JP); Akihiro ODA, Sakai City (JP)

(21) Appl. No.: 16/091,225

(22) PCT Filed: Apr. 7, 2017
(86) PCT No.: PCT/JP2017/014516

§ 371 Date: Oct. 4, 2018

(30) Foreign Application Priority Data
Apr. 15, 2016 (JP) 2016-081793

(51) Int. Cl. H01L 29/786

(52) U.S. Cl. CPC H01L 29/78648; H01L 27/1214; H01L 29/7869

(57) ABSTRACT

A gate driver TFT 30 includes: a gate electrode 30a; a channel portion 30d overlapping the gate electrode 30a with a gate insulating film 16 disposed therebetween and constructed from an oxide semiconductor film 17 that is a semiconductor film; a source electrode 30b connected to one end of the channel portion 30d; a drain electrode 30c connected to another end of the channel portion 30d; and an intermediate electrode 22 connected to the channel portion 30d at a position at which a distance L1 to the drain electrode 30c is greater than a distance L2 to the source electrode 30b.

### TECHNICAL FIELD

The present invention relates to a thin film transistor.

### BACKGROUND ART

Conventionally, a thin film transistor that is used as a switching element in a display panel, such as a liquid crystal panel, is known, as disclosed in Patent Document 1. The thin film transistor uses an oxide semiconductor material in the channel, and has a multi-gate structure in which two or more transistors are connected in series.

### RELATED ART DOCUMENT

### Patent Document

Patent Document 1: Japanese Unexamined Patent Application Publication No. 2010-266490

### Problem to be Solved by the Invention

In the multi-gate structure thin film transistor disclosed in Patent Document 1, oxygen release from the oxide semiconductor material that is the channel material is reduced, whereby high reliability is achieved. In addition, in the multi-gate structure thin film transistor, electric field concentration that is caused at an interface between a semiconductor and an insulating film in the vicinity of the drain electrode is reduced to some extent. However, compared with a thin film transistor configuring a pixel, a thin film transistor provided in a gate driver circuit formed on a display panel in a monolithic manner may have a higher drain voltage applied thereto. In this case, even when the multi-gate structure disclosed in Patent Document 1 is adopted, a failure may occur due to an electric field concentration (hot carrier phenomenon) caused in the vicinity of the drain electrode.

### DISCLOSURE OF THE PRESENT INVENTION

The present invention has been made in view of the above circumstances, and has the object of achieving an increase in drain breakdown voltage.

### Means for Solving the Problem

A thin film transistor according to the present invention includes a gate electrode; a channel portion overlapping the gate electrode with an insulating film disposed therebetween and being constructed from a semiconductor film; a source electrode connected to one end of the channel portion; a drain electrode connected to another end of the channel portion; and an intermediate electrode connected to the channel portion at a position at which a distance to the drain electrode is greater than a distance to the source electrode.

In this way, when a signal is supplied to the gate electrode, charges move successively from the source electrode to the intermediate electrode via the channel portion constructed from a semiconductor film, and from the intermediate electrode to the drain electrode via the channel portion, and the drain electrode is charged to a predetermined potential. The intermediate electrode disposed between the source electrode and the drain electrode is connected to the channel portion at the position at which the distance to the drain electrode is greater than the distance to the source electrode. Accordingly, the occurrence of electric field concentration that may be caused at the interface between the semiconductor film configuring the channel portion and the insulating film, particularly in the vicinity of the drain electrode, is preferably suppressed. Accordingly, even when a large potential difference is caused between the source electrode and the drain electrode, failure becomes less likely to occur in the thin film transistor, and the so-called drain breakdown voltage becomes high.

The present invention may include embodiments having the following preferable configurations.

(1) The thin film transistor may include a channel protection portion overlapping the channel portion, with a second insulating film disposed therebetween and lying over the channel portion on an opposite side from a gate electrode side, the channel protection portion being constructed from an electrically conductive film. When a charge is generated on the upper layer side of the second insulating film, a so-called back channel may be formed in the channel portion due to the charge, and a leak current may be generated. As a result, the operation reliability of the thin film transistor may be decreased. In this respect, the channel protection portion constructed from an electrically conductive film is disposed to overlap the channel portion with the second insulating film disposed therebetween. Accordingly, even when a charge is generated on the upper layer side of the second insulating film, an electric field due to the charge is blocked by the channel protection portion, making the formation of a back channel in the channel portion difficult. Thus, the operation reliability of the thin film transistor is maintained sufficiently high.

(2) The channel protection portion may be a second gate electrode to which a signal synchronized with a signal supplied to the gate electrode is supplied. In this way, a signal is supplied to the second gate electrode in synchronism with the gate electrode. Thus, the channel portion comes to have two charge circulation paths, making it possible to increase drain current. Accordingly, it becomes possible to suppress a decrease in drain current due to an increase in the length of the channel portion.

(3) The second gate electrode may be connected to the gate electrode through contact holes formed in the insulating film and the second insulating film. In this way, the signal supplied to the gate electrode is also supplied to the second gate electrode via the contact hole. Accordingly, the gate electrode and the second gate electrode can be easily synchronized.

(4) The channel protection portion may be disposed not to overlap the intermediate electrode and the drain electrode. In this way, compared with if the channel protection portion were disposed such that a part thereof overlaps the intermediate electrode or the drain electrode, it becomes possible to decrease the parasitic capacitance introduced between the channel protection portion and the intermediate electrode or the drain electrode. In addition, the distance between the intermediate electrode and the drain electrode is greater than the distance between the intermediate electrode and the source electrode. Accordingly, increased ease of forming of the channel protection portion can be obtained during manufacture.

(5) The source electrode and the drain electrode may be narrower than the channel portion. In this way, the area of overlap between the gate electrode and the source electrode, and the area of overlap between the gate electrode and the drain electrode are decreased. Accordingly, it becomes possible to decrease the parasitic capacitance introduced between the gate electrode and the source electrode, and the parasitic capacitance introduced between the gate electrode and the drain electrode.

(6) The intermediate electrode may be wider than the source electrode and the drain electrode. If the intermediate electrode were to have the same width as that of the source electrode and drain electrode, the effect of increasing the drain breakdown voltage may be spoiled. In this respect, as described above, by forming the intermediate electrode to be wider than the source electrode and the drain electrode, the effect of increasing the drain breakdown voltage can be sufficiently obtained.

(7) The gate electrode may include an opening portion at a position overlapping the intermediate electrode. In this way, the area of overlap between the gate electrode and the intermediate electrode is decreased. Thus, the parasitic capacitance introduced between the gate electrode and the intermediate electrode can be decreased.

(8) The semiconductor film may be an oxide semiconductor film. Generally, an oxide semiconductor, compared with amorphous silicon, has a large bandgap. Thus, when the semiconductor film is an oxide semiconductor film, a higher drain breakdown voltage can be obtained.

### Advantageous Effect of the Invention

According to the present invention, an increase in drain breakdown voltage can be achieved.

### BRIEF DESCRIPTION OF THE DRAWINGS

FIG. 1 is a schematic cross sectional view illustrating a cross section configuration of a liquid crystal panel according to the first embodiment of the present invention.

FIG. 2 is a plan view showing a wire configuration of pixel TFTs provided in the liquid crystal panel.

FIG. 3 is a cross sectional view of a pixel TFT provided in the liquid crystal panel.

FIG. 4 is a plan view of a gate driver TFT provided in the liquid crystal panel.

FIG. 5 is a cross sectional view taken along line A-A of FIG. 4.

FIG. 6 is a plan view of a gate driver TFT provided in the liquid crystal panel according to the second embodiment of the present invention.

FIG. 7 is a cross sectional view taken along line A-A of FIG. 6.

FIG. 8 is a plan view of a gate driver TFT provided in the liquid crystal panel according to the third embodiment of the present invention.

FIG. 9 is a cross sectional view taken along line B-B of FIG. 8.

FIG. 10 is a plan view of a gate driver TFT provided in the liquid crystal panel according to the fourth embodiment of the present invention.

FIG. 11 is a plan view of a gate driver TFT provided in the liquid crystal panel according to the fifth embodiment of the present invention.

FIG. 12 is a cross sectional view taken along line A-A of FIG. 11.

FIG. 13 is a plan view of a gate driver TFT provided in the liquid crystal panel according to the sixth embodiment of the present invention.

### MODE FOR CARRYING OUT THE INVENTION

### First Embodiment

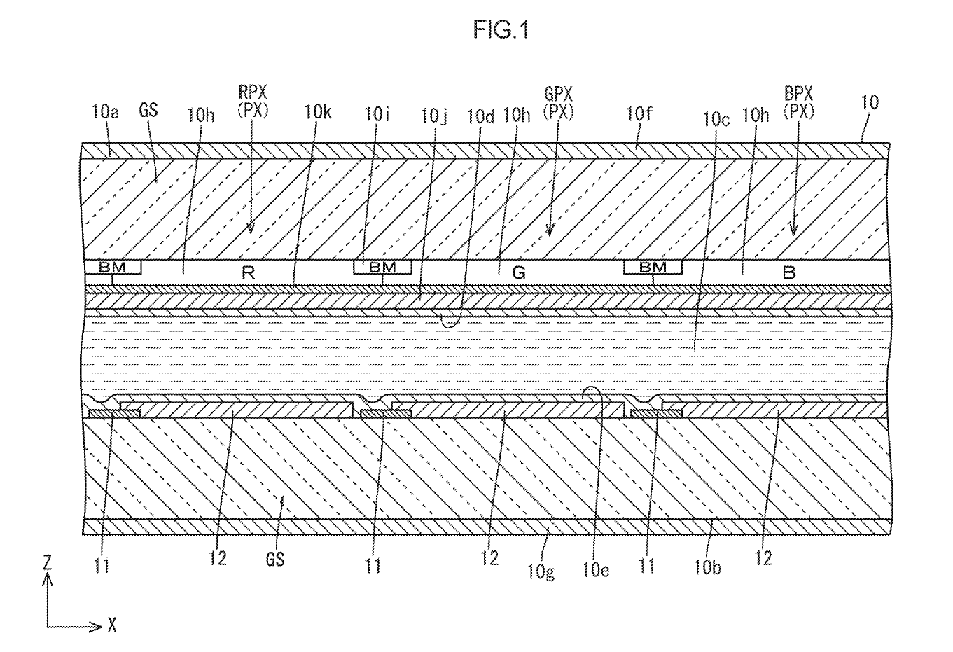

The first embodiment of the present invention will be described with reference to FIG. 1 to FIG. 4. In the present embodiment, a gate driver thin film transistor (a gate driver TFT) 30 provided in a liquid crystal panel (display panel) 10 will be described by way of example. In a part of each of the drawing figures, an X-axis, a Y-axis, and a Z-axis are indicated, the axis directions corresponding to the directions indicated in the drawing figures.

The configuration of the liquid crystal panel 10 will be described. As illustrated in FIG. 1, the liquid crystal panel 10 includes: a pair of transparent (highly optically transmissive) substrates 10a, 10b; and a liquid crystal layer 10c which is disposed between the substrates 10a, 10b and which includes a liquid crystal molecule constructed from a substance of which optical characteristics can be varied by application of an electric field. The substrates 10a, 10b are bonded to each other by means of a sealing agent (not illustrated), with a cell gap corresponding to the thickness of the liquid crystal layer 10c maintained therebetween. Each of the substrates 10a, 10b includes a substantially transparent glass substrate GS. On each glass substrate GS, a plurality of films are stacked by a known photolithography method, for example. Of the substrates 10a, 10b, the upper side (front side) is a CF substrate (counter substrate) 10a, and the back side (rear side) is an array substrate (thin film transistor substrate; active matrix substrate) 10b. Polarizing plates 10f, 10g are affixed to the outer surface of the substrates 10a, 10b, respectively. On the inner surface side of the substrates 10a, 10b, there are formed alignment films 10d, 10e respectively for aligning the liquid crystal molecules included in the liquid crystal layer 10c.

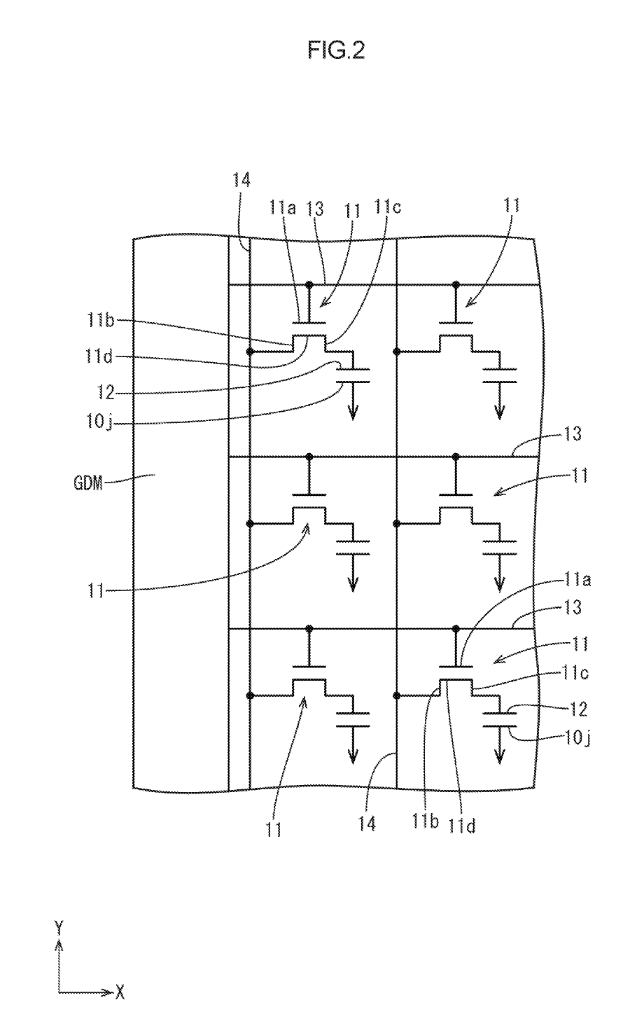

On the inner surface side of the array substrate 10b, in a display area in the center of the screen in which an image is displayed, as illustrated in FIG. 2, a number of pixel TFTs (Thin Film Transistor) 11 which are switching elements and a number of pixel electrodes 12 are arranged in a matrix. The pixel TFTs 11 and the pixel electrodes 12 are surrounded by a number of gate wires 13 and a number of source wires 14 forming a lattice. In other words, the pixel TFTs 11 and the pixel electrodes 12 are arranged in rows and columns at the intersecting portions of the gate wires 13 and the source wires 14 forming a lattice. The pixel electrodes 12 have a longitudinal quadrangular (rectangular) shape as viewed in plan, filling the area surrounded by the gate wires 13 and the source wires 14. On the inner surface side of the array substrate 10b, in a picture-frame shaped non-display area surrounding the display area, there is provided a gate driver circuit portion GDM which is connected to ends of the number of gate wires 13 and which supplies scan signals to the respective gate wires 13. The gate driver circuit portion GDM includes a number of gate driver TFTs (thin film transistor) 30, for example, in which an oxide semiconductor film 17 is used, as in the pixel TFTs 11 of which pixels PX are configured in the display area. The gate driver circuit portion GDM is formed on the array substrate 10b in a monolithic manner, using the oxide semiconductor film 17 as a base. The gate driver circuit portion GDM includes a buffer circuit for amplifying the scan signals. Gate driver TFTs 30 of which the buffer circuit is configured tend to have a higher applied drain voltage compared with the pixel TFTs 11 of which the pixels PX are configured in the display area. The gate driver circuit portion GDM extends in the Y-axis direction, i.e., the direction in which the gate wires 13 are arranged. The array substrate 10b may be provided with an auxiliary capacity wire (not illustrated) running in parallel with the gate wires 13 and intersecting the pixel electrodes 12.

As illustrated in FIG. 1, in the display area on the inner surface side of the CF substrate 10a, there is provided a color filter 10h including three colored portions of red (R), green (G), and blue (B). A plurality of each of the colored portions configuring the color filter 10h are arranged in rows and columns (in a matrix) in the row direction (X-axis direction) and the column direction (Y-axis direction) so as to overlap the respective pixel electrodes 12 on the array substrate 10b side, as viewed in plan. Between the colored portions configuring the color filter 10h, substantially lattice-shaped light-blocking portions (black matrix, light-blocking area) 10i are formed to prevent mixing of colors. The light-blocking portions 10i are disposed so as to overlap the gate wires 13 and the source wires 14, as viewed in plan. The colored portions configuring the color filter 10h have a film thickness greater than that of the light-blocking portions 10i, and are disposed so as to cover the light-blocking portions 10i. In the liquid crystal panel 10, individual pixels PX that are display units are configured of sets of the three colored portions R, G, and B of the color filter 10h, the three pixel electrodes 12 opposing the respective colored portions, and the three pixel TFTs 11 respectively connected to the pixel electrodes 12. The pixels PX include a red pixel RPX having a red colored portion, a green pixel GPX having a green colored portion, and a blue pixel BPX having a blue colored portion. The pixels RPX, GPX, and BPX of the respective colors are disposed on a plate surface of the liquid crystal panel 10 in a repetitive manner in the row direction (X-axis direction), thus configuring a pixel group. A number of the pixel groups are arranged side by side in the column direction (Y-axis direction).

As illustrated in FIG. 1, on a surface of the color filter 10h and the light-blocking portions 10i, an overcoat film 10k is disposed overlapping on the inner side. The overcoat film 10k is formed substantially throughout the inner surface of the CF substrate 10a as a solid film, and has a film thickness greater than or equal to that of the color filter 10h. On a surface of the overcoat film 10k, a counter electrode 10j is disposed overlapping on the inner side. The counter electrode 10j is formed substantially throughout the inner surface of the CF substrate 10a as a solid film. The counter electrode 10j is made of transparent electrode material such as indium tin oxide (ITO). The counter electrode 10j is maintained at a certain reference potential at all times. Accordingly, when the pixel TFTs 11 are driven and potentials are supplied to the pixel electrodes 12 connected to the pixel TFTs 11, potential differences are caused between the counter electrode 10j and the pixel electrodes 12. Based on the potential differences caused between the counter electrode 10j and the pixel electrodes 12, the alignment state of the liquid crystal molecules included in the liquid crystal layer 10c is changed. As a result, the polarization state of the transmitted light is changed, whereby the amount of light transmitted through the liquid crystal panel 10 is separately controlled on a pixel PX by pixel PX basis and a predetermined color image is displayed.

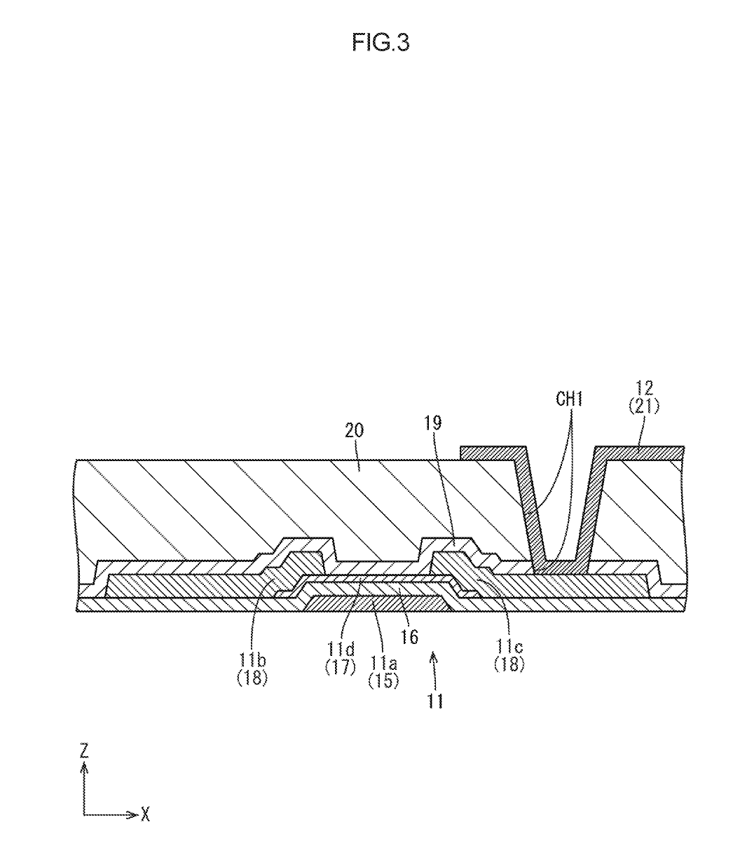

Various films stacked and formed on the inner surface side of the array substrate 10b will be described. As illustrated in FIG. 3, on the array substrate 10b, there are stacked and formed, in order from the lower layer (glass substrate GS) side: a first metal film (gate metal film) 15; a gate insulating film (insulating film) 16; an oxide semiconductor film (semiconductor film) 17; a second metal film (source metal film) 18; an interlayer insulating film (second insulating film) 19; a planarization film 20; and a transparent electrode film 21. In FIG. 3, illustration of an alignment film 10e which is stacked on the upper layer side of the transparent electrode film 21 is omitted.

The first metal film 15 is an electrically conductive film made of metal (such as Mo, Ti, Al, Cr, and Au), and preferably has a film thickness in a range of from 50 nm to 300 nm, for example. Preferably, the first metal film 15 is patterned by, for example, a photolithography method and dry etching after a film is formed by sputtering. The first metal film 15 mainly configures the gate wires 13 and a gate electrode 11a, which will be described later. As illustrated in FIG. 3, the gate insulating film 16 is stacked on the upper layer side of the first metal film 15. The gate insulating film 16 is configured from a laminated film of two layers made of inorganic material such as silicon oxide (SiO₂) and silicon nitride (SiNₓ). In FIG. 3, illustration of the layer structure of the gate insulating film 16 is omitted. The gate insulating film 16 is disposed between the first metal film 15 and the second metal film 18, which will be described later, and provides insulation therebetween. Preferably, the two layers of the gate insulating film 16 are continuously formed by a chemical vapor deposition (CVD) method. During the film formation, a rare gas element, such as argon gas, may be contained in the reaction gas. In this way, it becomes possible to decrease the film formation temperature and obtain a dense film, whereby a gate leak current can be reduced.

As illustrated in FIG. 3, the oxide semiconductor film 17 is stacked on the upper layer side of the gate insulating film 16, and is constructed from a thin film made of oxide semiconductor material. Preferably, the oxide semiconductor film 17 has a film thickness on the order of 30 to 100 nm, for example. The oxide semiconductor included in the oxide semiconductor film 17 may be an amorphous oxide semiconductor or a crystalline oxide semiconductor having a crystalline portion. Examples of crystalline oxide semiconductor include a polycrystalline oxide semiconductor, a microcrystalline oxide semiconductor, and a crystalline oxide semiconductor in which a c-axis is aligned generally perpendicularly to the layer surface. The oxide semiconductor film 17 may have a laminated structure of two or more layers. When the oxide semiconductor film 17 has a laminated structure, the oxide semiconductor film 17 may include a non-crystalline oxide semiconductor layer and a crystalline oxide semiconductor layer. Alternatively, the oxide semiconductor film 17 may include a plurality of crystalline oxide semiconductor layers having different crystal structures. The oxide semiconductor film 17 may include a plurality of non-crystalline oxide semiconductor layers. When the oxide semiconductor film 17 has a double-layer structure including an upper layer and a lower layer, the oxide semiconductor included in the upper layer preferably has an energy gap greater than an energy gap of the oxide semiconductor included in the lower layer. However, when the difference in energy gap between the layers is relatively small, the energy gap of the oxide semiconductor of the lower layer may be greater than the energy gap of the oxide semiconductor of the upper layer.

The materials and structures of non-crystalline oxide semiconductors and the crystalline oxide semiconductors, methods for forming the films thereof, configurations and the like of the oxide semiconductor film 17 having a laminated structure are described in Japanese Unexamined Patent Application Publication No. 2014-007399, for example. The contents of the disclosure of Japanese Unexamined Patent Application Publication No. 2014-007399 are incorporated herein by reference. The oxide semiconductor film 17 may include at least one metal element among In, Ga, and Zn. In the present embodiment, the oxide semiconductor film 17 includes an In—Ga—Zn—O-based semiconductor (such as an indium gallium zinc oxide), for example. Herein, the In—Ga—Zn—O-based semiconductor is a ternary oxide of In (indium), Ga (gallium), and Zn (zinc), where the ratio (composition ratio) of In, Ga, and Zn is not particularly limited and may include In: Ga:Zn=2:2:1, In:Ga:Zn=1:1:1, and In:Ga:Zn=1:1:2, for example. The oxide semiconductor film 17 may be formed of an oxide semiconductor film including an In—Ga—Zn—O-based semiconductor. The In—Ga—Zn—O-based semiconductor may be amorphous or crystalline. Preferably, the crystalline In—Ga—Zn—O-based semiconductor is made of a crystalline In—Ga—Zn—O-based semiconductor with a c-axis is generally perpendicularly aligned to the layer surface.

The crystal structure of the crystalline In—Ga—Zn—O-based semiconductor is disclosed in, for example: Japanese Unexamined Patent Application Publication No. 2014-007399 mentioned above; Japanese Unexamined Patent Application Publication No. 2012-134475; and Japanese Unexamined Patent Application Publication No. 2014-209727. The contents of the disclosures of Japanese Unexamined Patent Application Publication No. 2012-134475 and Japanese Unexamined Patent Application Publication No. 2014-209727 are incorporated herein by reference. A TFT having an In—Ga—Zn—O-based semiconductor layer has a high mobility (higher than that of an a-Si TFT by a factor of more than 20) and a low leak current (less than one-hundredth that of an a-Si TFT). Accordingly, the TFT may be preferably used as the gate driver TFTs 30 (such as the TFT included in the gate driver circuit portion (drive circuit) GDM disposed on the same glass substrate GS as that of the display area, in the vicinity of the display area including a plurality of pixels PX) and the pixel TFTs 11 (the TFTs configuring the pixels PX).

The oxide semiconductor film 17 may include another oxide semiconductor, instead of the In—Ga—Zn—O-based semiconductor. For example, the oxide semiconductor film 17 may include an In—Sn—Zn—O-based semiconductor (such as In₂O₃—SnO₂—ZnO; InSnZnO). The In—Sn—Zn—O-based semiconductor is a ternary oxide of In (indium), Sn (tin), and Zn (zinc). Alternatively, the oxide semiconductor film 17 may include, for example: an In—Al—Zn—O-based semiconductor; an In—Al—Sn—Zn—O-based semiconductor; a Zn—O-based semiconductor; an In—Zn—O-based semiconductor; a Zn—Ti—O-based semiconductor; a Cd—Ge—O-based semiconductor; a Cd—Pb—O-based semiconductor; CdO (cadmium oxide); a Mg—Zn—O-based semiconductor; an In—Ga—Sn—O-based semiconductor; an In—Ga—O-based semiconductor; a Zr—In—Zn—O-based semiconductor; or a Hf—In—Zn—O-based semiconductor.

As illustrated in FIG. 3, the second metal film 18 is stacked on the upper layer side of the oxide semiconductor film 17. The second metal film 18 is an electrically conductive film made of metal material (such as Mo, Ti, Al, Cr, a Au), and preferably has a film thickness in a range of from 150 nm to 500 nm, for example, which is greater than the film thickness of the first metal film 15. Preferably, the second metal film 18 is patterned by photolithography and dry etching after a film is formed by sputtering. The second metal film 18 mainly configures the source wires 14 and a source electrode 11b and a drain electrode 11c which will be described later. The interlayer insulating film 19 is stacked at least on the upper layer side of the second metal film 18. The interlayer insulating film 19 is made of inorganic material, such as silicon oxide (SiO₂) or silicon nitride (SiNₓ), and preferably has a film thickness in a range of from 200 nm to 300 nm, for example. Preferably, the interlayer insulating film 19 is patterned by photolithography and dry etching or wet etching after a film is formed by plasma CVD, for example. The patterning is preferably performed together with the planarization film 20, which will be described below, whereby a contact hole CH1 which will be described later is formed. The planarization film 20 is stacked on the upper layer side of the interlayer insulating film 19. The planarization film 20 is made of synthetic resin material such as acrylic resin (PMMA), and preferably has a film thickness on the order of 2 μm. That is, the film thickness of the planarization film 20 is greater than the film thickness of the interlayer insulating film 19, so that the surface of the array substrate 10b can be planarized. The planarization film 20 is preferably formed by slit coating or spin coating, for example. The interlayer insulating film 19 and the planarization film 20 are disposed between the second metal film 18 and oxide semiconductor film 17 and the transparent electrode film 21, and provide insulation therebetween. The transparent electrode film 21 is stacked on the upper layer side of the planarization film 20. The transparent electrode film 21, which is a type of electrically conductive film, is made of transparent electrode material such as indium zinc oxide (IZO) and has a film thickness on the order of 100 nm, for example. Preferably, the transparent electrode film 21 is formed by sputtering. The transparent electrode film 21 mainly configures the pixel electrodes 12.

The configuration of the pixel TFTs 11 will be described. As illustrated in FIG. 3, the pixel TFTs 11 include at least: a gate electrode 11a; a channel portion 11d; a source electrode lib connected to one end of the channel portion 11d; and a drain electrode 11c connected to another end of the channel portion 11d. The gate electrode 11a is constructed from the first metal film 15 from which the gate wires 13 are constructed and connected to the gate wires 13 to supply scan signals. The channel portion 11d is disposed to overlap the gate electrode 11a on the upper layer side, with the gate insulating film 16 disposed therebetween, and is constructed from the oxide semiconductor film 17. The source electrode lib is disposed on the upper layer side of the oxide semiconductor film 17 configuring the channel portion 11d, and is constructed from the second metal film 18 from which the source wires 14 are constructed. The end portion of the source electrode lib on the channel portion 11d side with respect to the X-axis direction is disposed so as to overlap the gate electrode 11a. The end portion of the source electrode 11b on the opposite side from the channel portion 11d side with respect to the X-axis direction is connected to the source wires 14. Accordingly, the source electrode lib is configured to receive a data signal from the source wires 14. The drain electrode 11c is constructed from the second metal film 18 from which the source wires 14 and the source electrode lib are constructed and opposed to the source electrode lib via an interval corresponding to the channel portion 11d. The end portion of the drain electrode 11c on the channel portion 11d side with respect to the X-axis direction is disposed so as to overlap the gate electrode 11a. The end portion of the drain electrode 11c on the opposite side from the channel portion 11d side with respect to the X-axis direction is connected to the pixel electrodes 12 via the contact hole CH1 opened and formed in the interlayer insulating film 19 and the planarization film 20. Accordingly, charges supplied to the drain electrode 11c can be supplied to the pixel electrodes 12. Thus, the pixel TFTs 11 have a single gate structure, as opposed to the gate driver TFTs 30, which will be described below. In the pixel TFTs 11 according to the present embodiment, no etch stop layer is formed on the channel portion 11d, and the lower surface of the end portion on the channel portion 11d side of the source electrode 11b is disposed so as to contact the upper surface of the oxide semiconductor film 17.

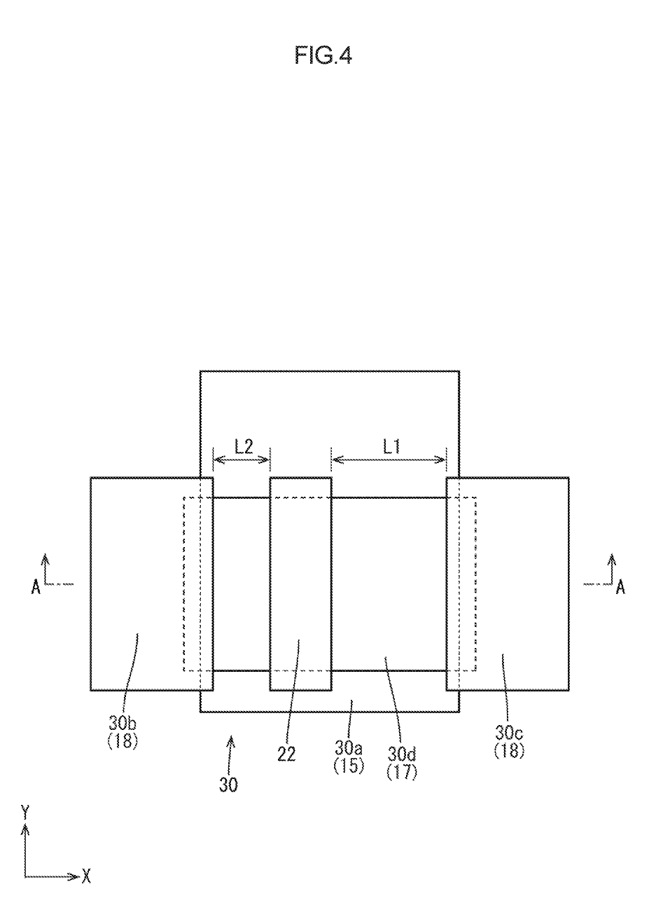

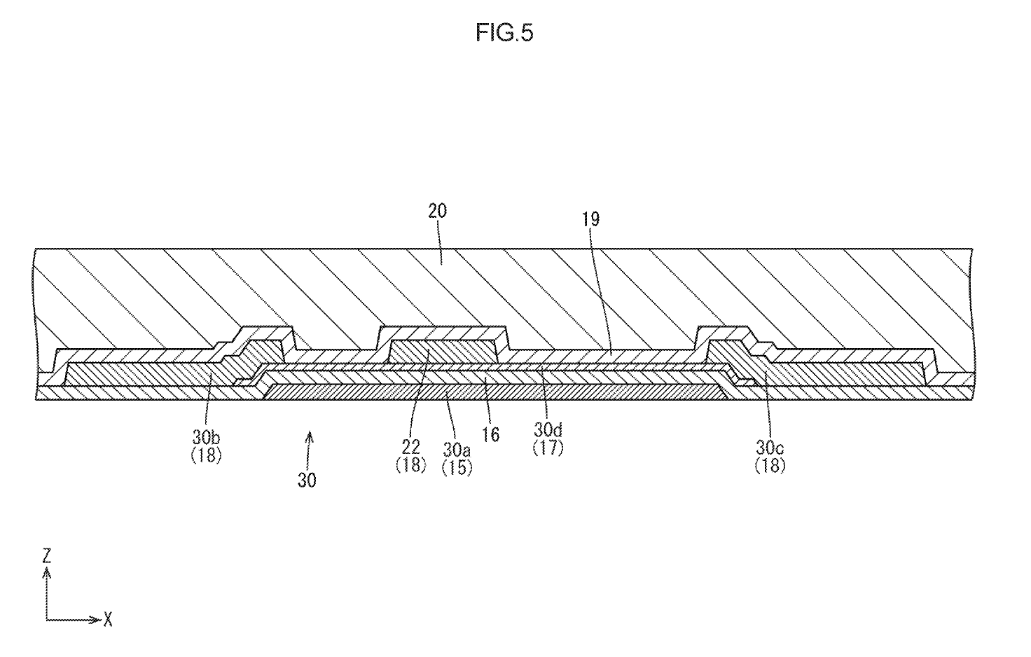

The configuration of the gate driver TFTs 30 provided in the gate driver circuit portion GDM will be described. As illustrated in FIG. 4 and FIG. 5, the gate driver TFTs 30 include at least: a gate electrode 30a; a channel portion 30d; a source electrode 30b connected to one end of the channel portion 30d; and a drain electrode 30c connected to another end of the channel portion 30d. The gate electrode 30a is constructed from the first metal film 15 from which the gate wires 13 are constructed and connected to a signal input wire or a signal input terminal of the gate driver circuit portion GDM. Accordingly, the gate electrode 30a can be supplied with an input signal that is input to the gate driver circuit portion GDM. The channel portion 30d is disposed so as to overlap the gate electrode 30a on the upper layer side, with the gate insulating film 16 disposed therebetween. The channel portion 30d is constructed from the oxide semiconductor film 17 and is formed in a band-like forming region so as to extend in the X-axis direction as viewed in plan. The source electrode 30b and the drain electrode 30c have a substantially equal width dimension (dimension with respect to the Y-axis direction that is the width direction). The width dimension is smaller than the width dimension of the gate electrode 30a and greater than the width dimension of the channel portion 30d. The source electrode 30b is disposed on the upper layer side of the oxide semiconductor film 17 configuring the channel portion 30d, and is constructed from the second metal film 18 from which the source wires 14 are constructed. The end portion of the source electrode 30b on the channel portion 30d side with respect to the X-axis direction is disposed so as to overlap the gate electrode 30a. On the other hand, the end portion of the source electrode 30b on the opposite side from the channel portion 30d side with respect to the X-axis direction is connected to a signal input wire or a signal input terminal of the gate driver circuit portion GDM. Accordingly, the source electrode 30b can be supplied with an input signal that is input to the gate driver circuit portion GDM. The drain electrode 30c is constructed from the second metal film 18 from which the source electrode 30b are constructed and opposed to the source electrode 30b via an interval corresponding to the channel portion 30d. The end portion of the drain electrode 30c on the channel portion 30d side with respect to the X-axis direction is disposed to overlap the gate electrode 30a. On the other hand, the end portion of the drain electrode 30c on the opposite side from the channel portion 30d side with respect to the X-axis direction is connected to a signal output wire or a signal output terminal of the gate driver circuit portion GDM. Accordingly, an input signal supplied from the source electrode 30b to the drain electrode 30c via the channel portion 30d can be output. In the gate driver TFTs 30 according to the present embodiment, as in the pixel TFTs 11, no etch stop layer is formed on the channel portion 30d. The lower surface of the end portion on the channel portion 30d side of the source electrode 30b is disposed so as to contact the upper surface of the oxide semiconductor film 17.

As illustrated in FIG. 4 and FIG. 5, the gate driver TFTs 30 according to the present embodiment includes an intermediate electrode 22 as an electrode connected to the channel portion 30d, in addition to the source electrode 30b and the drain electrode 30c. The intermediate electrode 22 is constructed from the second metal film 18 from which the source electrode 30b and the drain electrode 30c are constructed and disposed to lie over the channel portion 30d on the upper layer side (opposite side from the gate insulating film 16 side). The intermediate electrode 22 is connected to a position of the channel portion 30d between the source electrode 30b and the drain electrode 30c with respect to the length direction (X-axis direction). The position is such that a distance L1 to the drain electrode 30c is greater than a distance L2 to the source electrode 30b (position such that “L1>L2”). The distance L1 is the channel length from the intermediate electrode 22 to the drain electrode 30c. The distance L2 smaller than the distance L1 is the channel length from the source electrode 30b to the intermediate electrode 22. The intermediate electrode 22 has a width dimension (dimension with respect to the Y-axis direction that is the width direction) which is substantially equal to the width dimension of each of the source electrode 30b and the drain electrode 30c. The intermediate electrode 22, however, has a length dimension (dimension with respect to the X-axis direction that is the length direction) which is smaller than the length dimension of each of the source electrode 30b and the drain electrode 30c. The intermediate electrode 22, along the length thereof with respect to the X-axis direction, overlaps the channel portion 30d.

In this configuration, when an input signal is supplied to the gate electrode 30a, the gate driver TFT 30 is driven. Then, a charge based on the input signal supplied to the source electrode 30b successively moves from the source electrode 30b to the intermediate electrode 22 via the channel portion 30d, and from the intermediate electrode 22 to the drain electrode 30c and the pixel electrode 12 via the channel portion 30d, and the drain electrode 30c comes to have a predetermined potential. That is, the gate driver TFTs 30 according to the present embodiment may be said to have a dual-gate structure (multi-gate structure) in which, as opposed to the pixel TFTs 11 having a single gate structure, two unit TFTs that are driven via the common gate electrode 30a are connected in series. In this case, the intermediate electrode 22 functions as a pseudo-drain electrode in one unit TFT having the source electrode 30b, and functions as a pseudo-source electrode in the other unit TFT having the drain electrode 30c. In the gate driver TFTs 30 having the dual-gate structure, there has been the concern that an electric field concentration (a so-called hot carrier phenomenon) may be caused at an interface between the oxide semiconductor film 17 configuring the channel portion 30d and the gate insulating film 16 in the vicinity of, among the source electrode 30b, intermediate electrode 22, and drain electrode 30c connected to the channel portion 30d, the drain electrode 30c in particular. In the gate driver TFTs 30 according to the present embodiment, the intermediate electrode 22 disposed between the source electrode 30b and the drain electrode 30c is connected to the channel portion 30d in a position such that the distance L1 to the drain electrode 30c is greater than the distance L2 to the source electrode 30b. Accordingly, the occurrence of electric field concentration that may be caused at the interface between the oxide semiconductor film 17 configuring the channel portion 30d and the gate insulating film 16 in the vicinity of the drain electrode 30c in particular is preferably suppressed. Accordingly, even when a large potential difference is caused between the source electrode 30b and the drain electrode 30c, a failure becomes less likely to occur in the gate driver TFT 30, and the so-called drain breakdown voltage becomes high. In particular, the gate driver TFTs 30 provided in the gate driver circuit portion GDM, compared with the pixel TFTs 11 configuring the pixels PX in the display area, tend to have a high applied drain voltage (potential difference caused between the source electrode 30b and the drain electrode 30c). Thus, even when the applied drain voltage is increased by the adoption of the dual-gate structure, failure is less likely to occur and high operation reliability can be obtained. In addition, the channel portion 30d is constructed from the oxide semiconductor film 17 in which an oxide semiconductor material that, compared with amorphous silicon, generally has a large bandgap is used, making the drain breakdown voltage even higher.

As described above, the gate driver TFT (thin film transistor) 30 according to the present embodiment includes: the gate electrode 30a; the channel portion 30d which overlaps the gate electrode 30a with the gate insulating film (insulating film) 16 disposed therebetween, and which is constructed from the oxide semiconductor film 17 that is a semiconductor film; the source electrode 30b connected to one end of the channel portion 30d; the drain electrode 30c connected to another end of the channel portion 30d; and the intermediate electrode 22 which is connected to the channel portion 30d in a position such that the distance L1 to the drain electrode 30c is greater than the distance L2 to the source electrode 30b.

In this way, when a signal is applied to the gate electrode 30a, a charge successively moves from the source electrode 30b to the intermediate electrode 22 via the channel portion 30d constructed from the oxide semiconductor film 17, and from the intermediate electrode 22 to the drain electrode 30c via the channel portion 30d, whereby the drain electrode 30c is charged to a predetermined potential. The intermediate electrode 22 disposed between the source electrode 30b and the drain electrode 30c is connected to the channel portion 30d at a position such that the distance L1 to the drain electrode 30c is greater than the distance L2 to the source electrode 30b. Accordingly, the occurrence of electric field concentration that may be caused at the interface between the oxide semiconductor film 17 configuring the channel portion 30d and the gate insulating film 16, in the vicinity of the drain electrode 30c in particular, is preferably suppressed. Accordingly, even when a large potential difference is caused between the source electrode 30b and the drain electrode 30c, failure becomes less likely to occur in the gate driver TFTs 30, and the so-called drain breakdown voltage becomes high.

The semiconductor film configuring the channel portion 30d is the oxide semiconductor film 17. Generally, an oxide semiconductor has a large bandgap compared with amorphous silicon. Thus, by using the oxide semiconductor film 17 as the semiconductor film configuring the channel portion 30d, a higher drain breakdown voltage can be obtained.

### Second Embodiment

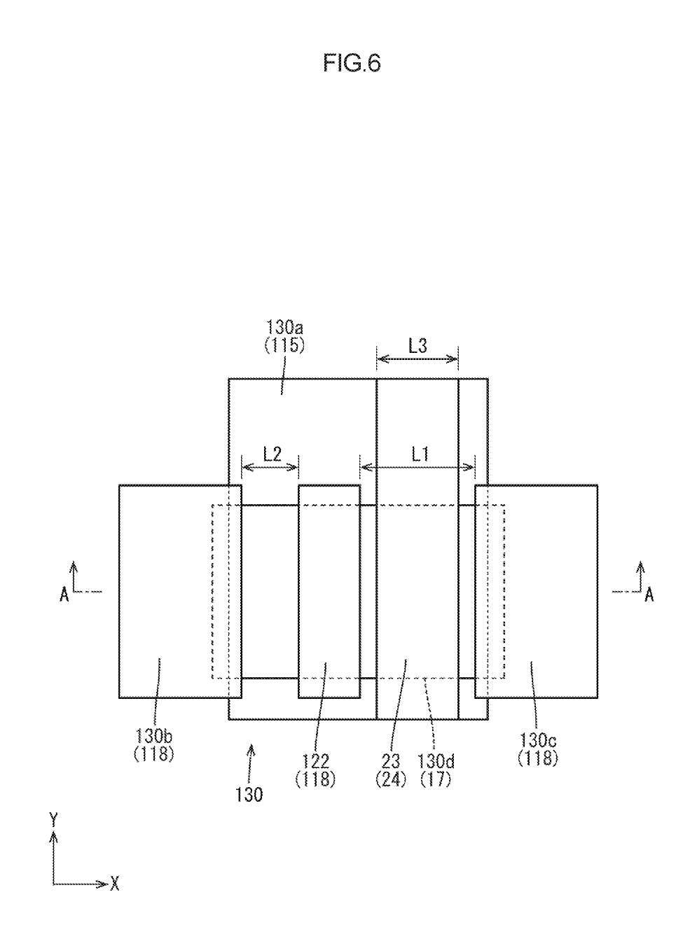

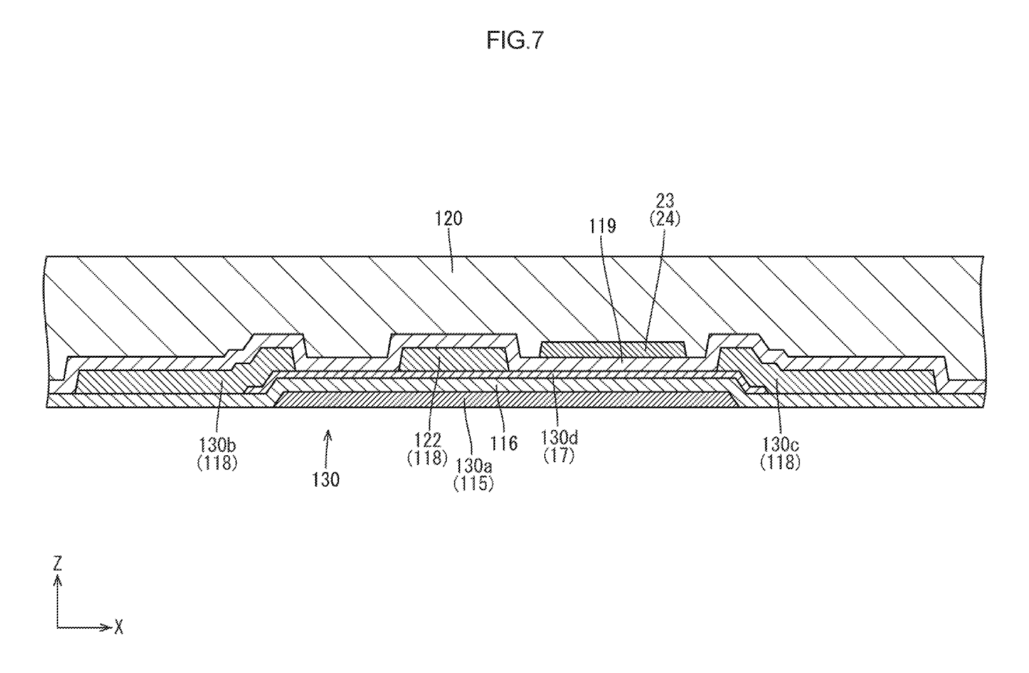

The second embodiment of the present invention will be described with reference to FIGS. 6 and 7. The second embodiment is provided with a channel protection portion 23 for protecting the channel portion 130d. Redundant descriptions of structures, operations, and effects similar to those of the first embodiment described above will be omitted.

As illustrated in FIG. 6 and FIG. 7, a gate driver TFT 130 according to the present embodiment includes a channel protection portion 23 overlapping the channel portion 130d. The channel protection portion 23 is disposed so as to overlap the channel portion 130d via an interlayer insulating film (second insulating film) 119 which is disposed to lie over the channel portion 130d on the upper side, i.e., on the opposite side from the gate electrode 130a (gate insulating film 116) side. The channel protection portion 23 is constructed from a third metal film (electrically conductive film) 24 disposed between an interlayer insulating film 119 and a planarization film 120. The third metal film 24 configuring the channel protection portion 23 is an electrically conductive film made of metal material (such as Mo, Ti, Al, Cr, and Au), as in the case of the first metal film 115 and the second metal film 118. In this case, due to the ON/OFF operation and the like of the gate driver TFT 130, for example, a charge may be drawn to the film interface of the planarization film 120 (interlayer insulating film 119), and the charge may be diffused in the planarization film 120, resulting in the presence of a charge at the interface between the planarization film 120 and the interlayer insulating film 119. If a so-called back channel is formed in the channel portion 130d due to the charge, leak current may be generated and the operation reliability of the gate driver TFT 130 may be decreased. In this respect, the channel protection portion 23 constructed from the third metal film 24 is disposed so as to overlap the channel portion 130d with the interlayer insulating film 119 disposed therebetween. Accordingly, even if a charge is generated on the upper layer side of the interlayer insulating film 119, an electric field due to the charge is blocked by the channel protection portion 23, making the formation of a back channel in the channel portion 130d difficult. Accordingly, the operation reliability of the gate driver TFT 130 is maintained sufficiently high.

The channel protection portion 23 has a length dimension (dimension with respect to the X-axis direction that is the length direction) L3 which is smaller than a distance L1 between the intermediate electrodes 122 and the drain electrode 130c. The channel protection portion 23 is disposed so as to be non-overlapping with respect to both the intermediate electrodes 122 and the drain electrode 130c. In this configuration, compared with if a part of the channel protection portion were to be disposed so as to overlap the intermediate electrodes 122 or the drain electrode 130c, it becomes possible to decrease the parasitic capacitance introduced between the channel protection portion 23 and the intermediate electrodes 122 or the drain electrode 130c. Further, the distance L1 between the intermediate electrode 122 and the drain electrode 130c is greater than the distance L2 between the intermediate electrodes 122 and the source electrode 130b. Accordingly, during manufacture, increased ease of forming of the second gate electrode can be obtained. The channel protection portion 23 has a width dimension (dimension with respect to the Y-axis direction that is the width direction) which is greater than the width dimension of each of the intermediate electrodes 122 and the drain electrode 130c, and which is substantially the same as the width dimension of the gate electrode 130a.

As described above, the present embodiment is provided with the channel protection portion 23 which overlaps the channel portion 130d with the interlayer insulating film (second insulating film) 119 disposed therebetween, the interlayer insulating film 119 lying over the channel portion 130d on the opposite side from the gate electrode 130a side. The channel protection portion 23 is constructed from the third metal film 24 that is an electrically conductive film. If a charge is generated on the upper layer side of the interlayer insulating film 119, a so-called back channel may be formed in the channel portion 130d due to the charge, and a leak current may be generated. As a result, the operation reliability of the gate driver TFT 130 may be decreased. In this respect, the channel protection portion 23 constructed from the third metal film 24 that is an electrically conductive film is disposed so as to overlap the channel portion 130d with the interlayer insulating film 119 disposed therebetween. Accordingly, even if a charge is generated on the upper layer side of the interlayer insulating film 119, the electric field due to the charge is blocked by the channel protection portion 23, making the formation of a back channel in the channel portion 130d difficult. Thus, the operation reliability of the gate driver TFT 130 is maintained sufficiently high.

The channel protection portion 23 is disposed so as to be non-overlapping with respect to the intermediate electrode 122 and the drain electrode 130c. In this way, compared with if a part of the channel protection portion were to be disposed so as to overlap the intermediate electrode 122 or the drain electrode 130c, it becomes possible to decreased the parasitic capacitance introduced between the channel protection portion 23 and the intermediate electrodes 122 or the drain electrode 130c. In addition, the distance L1 between the intermediate electrode 122 and the drain electrode 130c is greater than the distance L2 between the intermediate electrode 122 and the source electrode 130b. Thus, during manufacture, increased ease of forming of the channel protection portion 23 can be obtained.

### Third Embodiment

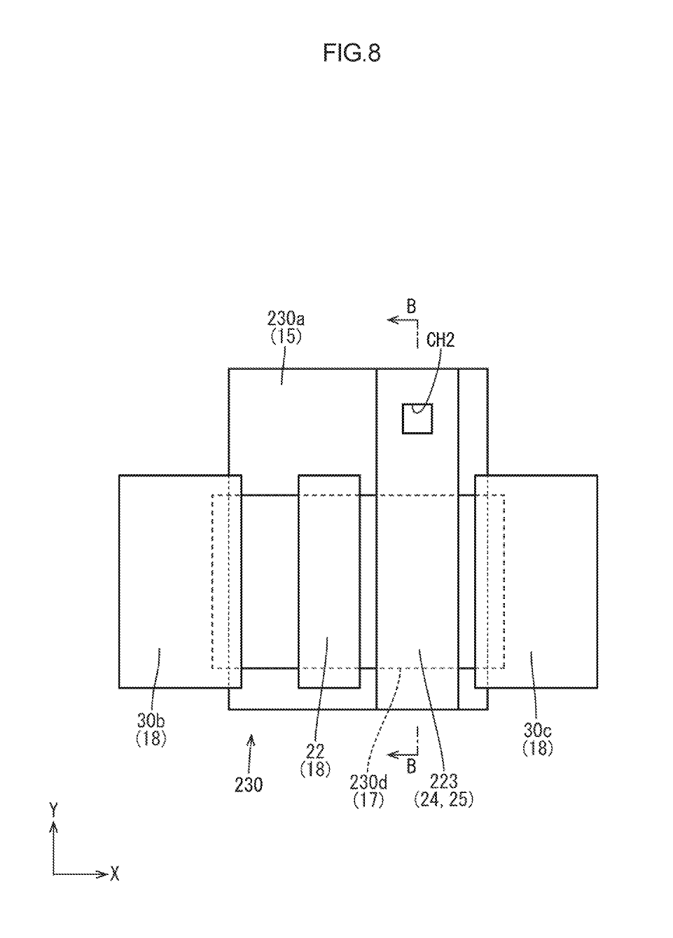

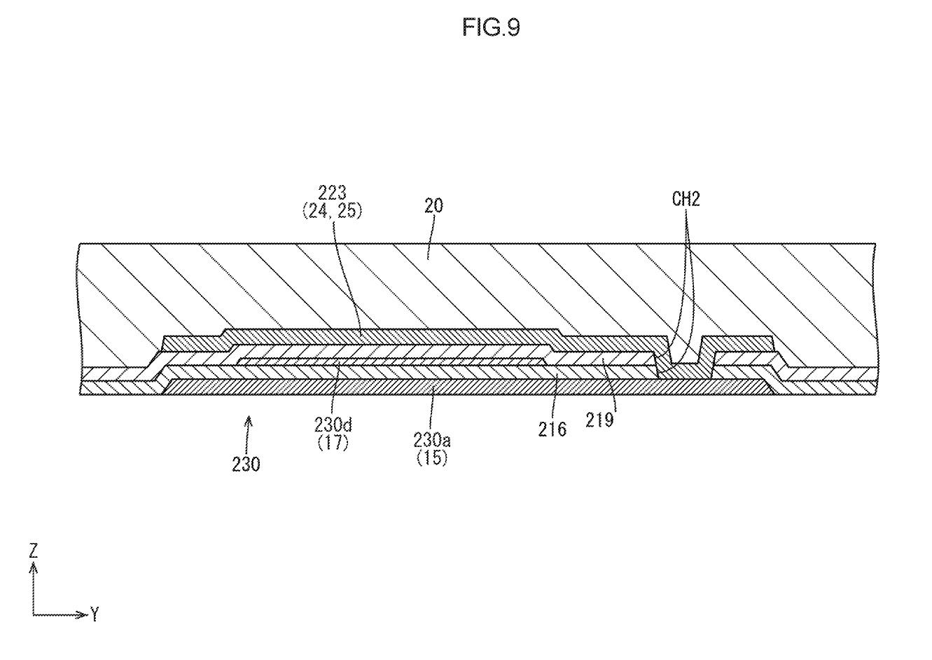

The third embodiment of the present invention will be described with reference to FIGS. 8 and 9. In the third embodiment, a channel protection portion 223 is modified from that of the second embodiment. Redundant descriptions of structures, operations, and effects similar to those of the second embodiment will be omitted.

As illustrated in FIG. 8 and FIG. 9, the channel protection portion 223 of a gate driver TFT 230 according to the present embodiment is connected to a gate electrode 230a via a contact hole CH2 opened and formed in the gate insulating film 216 and the interlayer insulating film 219. Accordingly, the channel protection portion 223 has the same potential as that of the gate electrode 230a, and an input signal supplied to the gate electrode 230a is also supplied to the channel protection portion 223. That is, the channel protection portion 223 functions as a second gate electrode 25 to which an input signal synchronized with the input signal supplied to the gate electrode 230a is supplied. In this configuration, when the same input signal is supplied to the gate electrode 230a and the second gate electrode 25, there will be two charge circulation paths in the channel portion 230d, one of which is on the gate electrode 230a side and the other of which is on the second gate electrode 25 side, making it possible to increase whereby the drain current. Accordingly, it becomes possible to suppress a decrease in drain current due to an increased in the length of the channel portion 230d.

As described above, in the present embodiment, the channel protection portion 223 constitutes the second gate electrode 25 to which a signal synchronized with the signal supplied to the gate electrode 230a is supplied. In this way, a signal is supplied to the second gate electrode 25 in synchronism with the gate electrode 230a, and there will be two charge circulation paths in the channel portion 230d. Accordingly, it becomes possible to increase the drain current. Thus, it becomes possible to suppress a decrease in drain current due to an increased in the length of the channel portion 230d.

The second gate electrode 25 is connected to the gate electrode 230a via the contact hole CH2 opened and formed in the gate insulating film 216 and the interlayer insulating film 219. In this way, a signal supplied to the gate electrode 230a is also supplied to the second gate electrode 25 via the contact hole CH2. Accordingly, the gate electrode 230a and the second gate electrode 25 can be easily synchronized.

### Fourth Embodiment

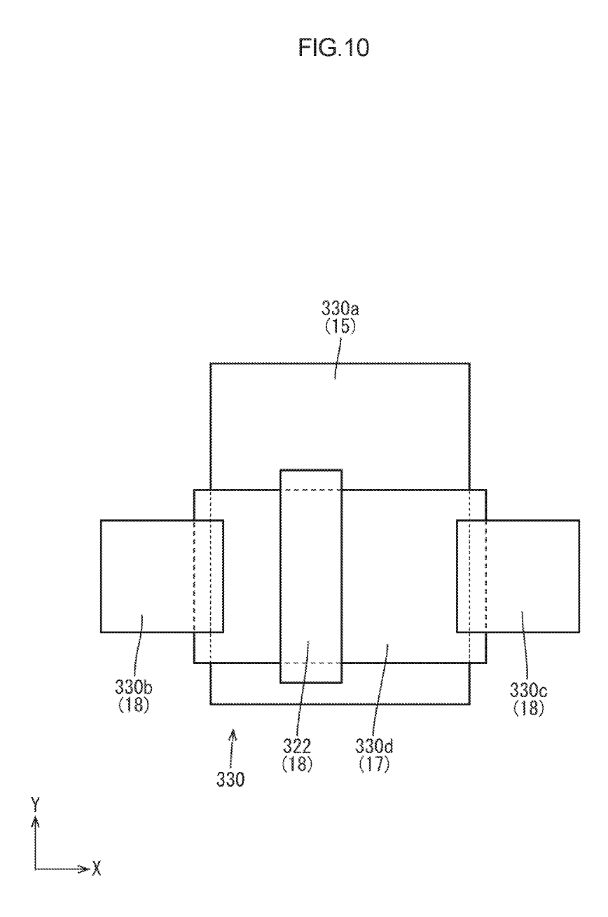

The fourth embodiment of the present invention will be described with reference to FIG. 10. In the fourth embodiment, the structures of a source electrode 330b and a drain electrode 330c are modified from the first embodiment. Redundant descriptions of structures, operations, and effects similar to those of the first embodiment will be omitted.

As illustrated in FIG. 10, in the present embodiment, the source electrode 330b and the drain electrode 330c of a gate driver TFT 330 are narrower than a channel portion 330d. The source electrode 330b and the drain electrode 330c have a width dimension (dimension with respect to the Y-axis direction that is the width direction) which is smaller than a width dimension of an intermediate electrode 322, and which is also smaller than a width dimension of the channel portion 330d. In this configuration, compared with the configuration of the first embodiment, the area of overlap between the gate electrode 330a and the source electrode 330b, and the area of overlap between the gate electrode 330a and the drain electrode 330c are decreased. Accordingly, it is possible to decrease the parasitic capacitance introduced between the gate electrode 330a and the source electrode 330b, and the parasitic capacitance introduced between the gate electrode 330a and the drain electrode 330c. In addition, the intermediate electrode 322 is wider than the channel portion 330d, the source electrode 330b, and the drain electrode 330c. Accordingly, compared with if the intermediate electrode had the same width as that of the source electrode 330b and the drain electrode 330c, it becomes possible to obtain the effect of achieving a sufficient increase in drain breakdown voltage.

As described above, in the present embodiment, the source electrode 330b and the drain electrode 330c are narrower than the channel portion 330d. In this way, the area of overlap between the gate electrode 330a and the source electrode 330b, and the area of overlap between the gate electrode 330a and the drain electrode 330c are decreased. Accordingly, it is possible to decrease the parasitic capacitance introduced between the gate electrode 330a and the source electrode 330b, and the parasitic capacitance introduced between the gate electrode 330a and the drain electrode 330c.

The intermediate electrode 322 is wider than the source electrode 330b and the drain electrode 330c. If the intermediate electrode were to have the same width as those of the source electrode 330b and the drain electrode 330c, the effect of increasing the drain breakdown voltage may be spoiled. In this respect, as described above, the intermediate electrode 322 is wider than the source electrode 330b and the drain electrode 330c, whereby the effect of increasing the drain breakdown voltage can be sufficiently obtained.

### Fifth Embodiment

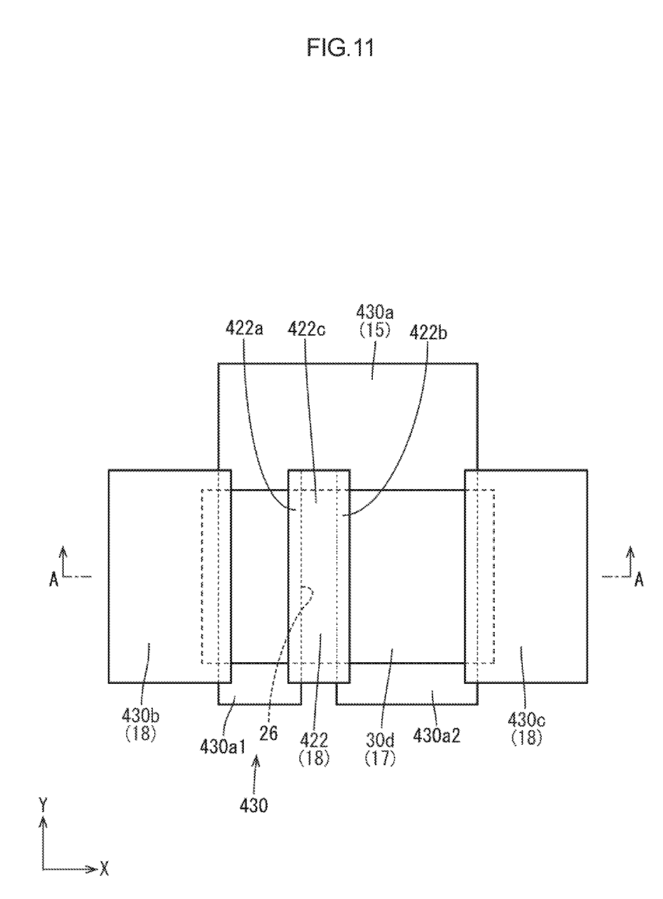

The fifth embodiment of the present invention will be described with reference to FIGS. 11 12. In the fifth embodiment, the structure of a gate electrode 430a is modified from the first embodiment. Redundant descriptions of structures, operations, and effects similar to those of the first embodiment will be omitted.

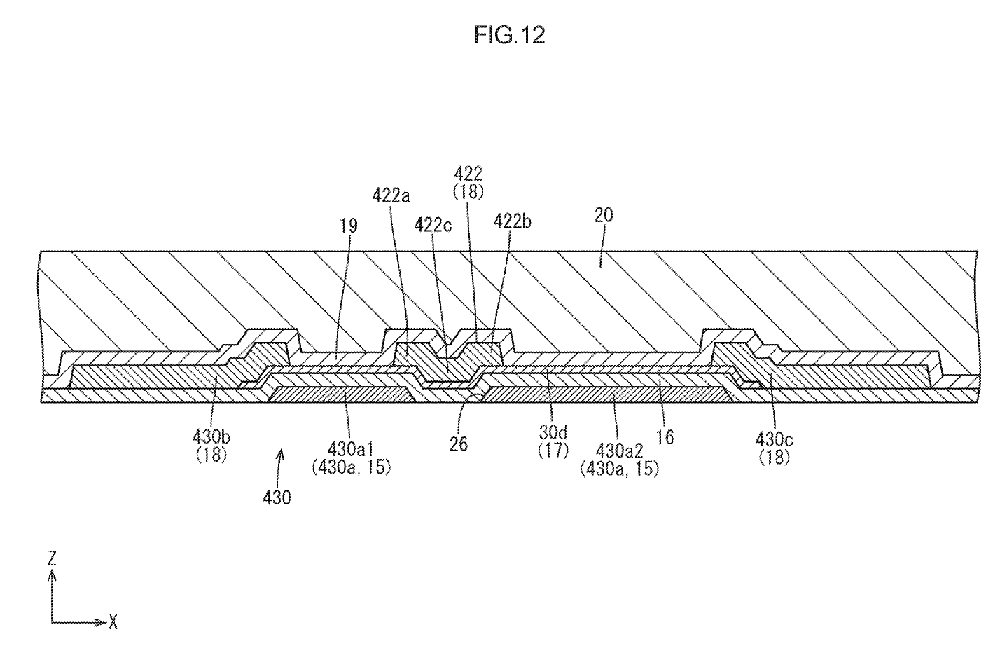

As illustrated in FIG. 11 and FIG. 12, in the present embodiment, the gate electrode 430a of a gate driver TFT 430 includes an opening portion (slit) 26 in a position overlapping an intermediate electrode 422. In the gate electrode 430a, the opening portion 26 is formed in a band-like region overlapping a central portion 422c between both end portions 422a, 422b of the intermediate electrode 422 with respect to the length direction (X-axis direction). Accordingly, of the intermediate electrode 422, the end portion 422a on the source electrode 430b side (the left side in FIG. 11 and FIG. 12) and the end portion 422b on the drain electrode 430c side (on the right side in FIG. 11 and FIG. 12) with respect to the X-axis direction respectively overlap the gate electrode 430a. However, the central portion 422c of the intermediate electrode 422 with respect to the X-axis direction does not overlap the gate electrode 430a. Thus, the area of overlap between the gate electrode 430a and the intermediate electrode 422, compared with the first embodiment, is decreased by the central portion 422c of the intermediate electrode 422. This makes it possible to reduce the parasitic capacitance introduced between the gate electrode 430a and the intermediate electrode 422. The gate electrode 430a is generally bifurcated by the opening portion 26 into a portion (first gate portion) 430a1 which overlaps both the source electrode 430b and the intermediate electrode 422 and functions as the gate electrode of one unit TFT, and a portion (second gate portion) 430a2 which overlaps both the drain electrode 430c and the intermediate electrode 422 and functions as the gate electrode of the other unit TFT.

As described above, according to the present embodiment, the gate electrode 430a includes the opening portion 26 in the position overlapping the intermediate electrode 422. In this way, the area of overlap between the gate electrode 430a and the intermediate electrode 422 is decreased, making it possible to reduce the parasitic capacitance introduced between the gate electrode 430a and the intermediate electrode 422.

### Sixth Embodiment

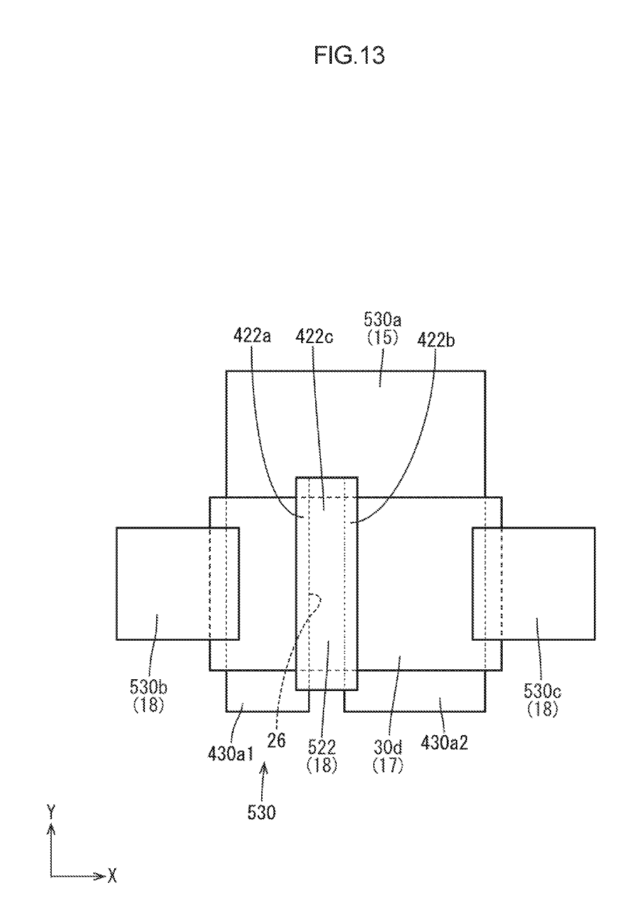

The sixth embodiment of the present invention will be described with reference to FIG. 13. In the sixth embodiment, the fourth and fifth embodiments are combined. Redundant descriptions of structures, operations, and effects similar to those of the fourth and fifth embodiment will be omitted.

As illustrated in FIG. 13, in a gate driver TFT 530 according to the present embodiment, a source electrode 530b and a drain electrode 530c are narrower than a channel portion 530d. In addition, an opening portion 526 is formed in a position overlapping an intermediate electrode 522 of a gate electrode 530a. In this configuration, compared with the configuration of the first embodiment, the area of overlap between the gate electrode 530a and the source electrode 530b, and the area of overlap between the gate electrode 530a and the drain electrode 530c are decreased. In addition, the area of overlap between the gate electrode 530a and the intermediate electrode 522 is decreased. Accordingly, it is possible to decrease the parasitic capacitance introduced between the gate electrode 530a and the source electrode 530b, and the parasitic capacitance introduced between the gate electrode 530a and the drain electrode 530c. Furthermore, it is possible to decrease the parasitic capacitance introduced between the gate electrode 530a and the intermediate electrode 522.

### Other Embodiments

The present invention is not limited to the embodiments described above and illustrated in the drawings, and may include the following exemplary embodiments in the technical scope of the present invention.

(1) In the foregoing embodiments, a gate driver TFT having a dual-gate structure in which two unit TFTs are connected in series has been described by way of example. However, the present invention is applicable to a gate driver TFT having a triple-gate structure (multi-gate structure) in which three unit TFTs are connected in series. The present invention is also applicable to a gate driver TFT having a multi-gate structure in which four or more unit TFTs are connected in series.

(2) Other than as illustrated for the foregoing embodiments, the specific ratio of the distance L1 and the distance L2 may be modified, as appropriate.

(3) In the foregoing embodiments, the case has been described in which the intermediate electrode is wider than the channel portion. However, the intermediate electrode may have the same width as or a narrower width than the width of the channel portion.

(4) In the foregoing embodiments, the case has been described in which the source electrode and the drain electrode have the same width. However, the source electrode and the drain electrode may have different width dimensions.

(5) In the foregoing embodiments, the case has been described in which the gate driver circuit portion including the gate driver TFTs is provided in the non-display area of the array substrate. However, the gate driver circuit portion may be provided in the display area of the array substrate. Such configuration may be preferable when the liquid crystal panel has an odd outer shape other than rectangular (such as an outer shape including a curved line or inclined line).

(6) In the second and third embodiments, the case has been described in which the length dimension L3 of the channel protection portion (second gate electrode) is smaller than the distance L1 between the intermediate electrode and the drain electrode. However, the length dimension of the channel protection portion (second gate electrode) may be the same as or greater than the distance L1 between the intermediate electrode and the drain electrode.

(7) In the second and third embodiments, the case has been described in which the width dimension of the channel protection portion (second gate electrode) is equal to the width dimension of the gate electrode. However, the width dimension of the channel protection portion (second gate electrode) may be smaller than the width dimension of the gate electrode. In this case, preferably, the channel protection portion (second gate electrode) may be wider than the channel portion in order to exploit the protecting function of the channel portion. This, however, may not be the case.

(8) Other than as illustrated in the drawings with reference to the third embodiment, the specific plane arrangement, number of installations, size as viewed in plan and the like of the contact hole connecting the channel protection portion and the gate electrode may be modified, as appropriate.

(9) In the fourth and sixth embodiments, the case has been described in which the intermediate electrode is wider than the source electrode and the drain electrode. However, the intermediate electrode may have the same width as or a narrower width than the width of the source electrode and the drain electrode.

(10) Other than the fifth and sixth embodiments, the specific forming area, planar shape, number of installations, size as viewed in plan and the like of the opening portion in the gate electrode may be modified, as appropriate.

(11) The configurations described in the second and third embodiments may be combined with the configurations described in the fourth to sixth embodiments, as appropriate.

(12) In the foregoing embodiments, an array substrate having an oxide semiconductor film as a semiconductor film has been described by way of example. It is also possible to use other materials for the semiconductor film, such as continuous grain (CG) silicon which is a type of polysilicon (polycrystallized silicon (polycrystalline silicon), or amorphous silicon.

(13) The specific materials of insulating films, such as the gate insulating film, the interlayer insulating film, and the planarization film, may be modified, as appropriate, from those described in the foregoing embodiments.

(14) The specific materials of metal films, such as the first metal film, the second metal film, and the third metal film may be modified, as appropriate, from those described in the foregoing embodiments. The laminated structure of the metal films may also be modified, as appropriate. For example, the number of stacks may be modified, a single-layer structure may be adopted, or an alloy structure may be adopted.

(15) The specific transparent electrode material used in the transparent electrode film may be modified, as appropriate, from that of the foregoing embodiments. Specifically, a transparent electrode material such as ITO (Indium Tin Oxide) or ZnO (Zinc Oxide) may be used.

(16) In the foregoing embodiments, the case has been described in which, in a liquid crystal panel having a VA mode as an operation mode, only one layer of a transparent electrode film is provided on an array substrate. However, two layers of transparent electrode films may be provided with an interlayer insulating film disposed therebetween. In this case, it is possible, for example, for one transparent electrode film to configure a pixel electrode and the other transparent electrode film to configure an auxiliary capacity electrode for forming a capacitance between the auxiliary capacity electrode and the pixel electrode.

(17) In the foregoing embodiments, the case has been described in which no etch stop layer is formed over the channel portion of the gate driver TFT, and the lower surface of the end portion on the channel portion side of the source electrode is disposed in contact with the upper surface of the oxide semiconductor film. However, an etch stop-type gate driver TFT may be adopted in which an etch stop layer is formed on the upper layer side of the channel portion.

(18) In the foregoing embodiments, a liquid crystal panel having a VA mode as an operation mode has been described by way of example. However, the present invention is also applicable with respect to a gate driver TFT of a liquid crystal panel having other operation modes, such as an in-plane switching (IPS) mode or a fringe field switching (FFS) mode.

(19) In the foregoing embodiments, examples have been described in which the liquid crystal panel pixels have the three colors of red, green, and blue. However, the present invention is also applicable to a gate driver TFT of a liquid crystal panel provided with pixels of four colors including yellow, for example, as well as red, green, and blue.

(20) The present invention also includes the liquid crystal panel according to the foregoing embodiments to which a functional panel, such as a touch panel or a parallax barrier panel (switch liquid crystal panel) can be attached in a stacked manner.

(21) In the foregoing embodiments, a gate driver TFT provided in a liquid crystal panel has been described by way of example. However, the present invention is also applicable to a gate driver TFT provided in other types of display panel (such as an organic EL panel, a plasma display panel (PDP), an electrophoretic display (EPD) panel, and a micro electromechanical systems (MEMS) display panel.

(22) In the foregoing embodiments, the case has been described in which the pixel TFTs configuring the pixels in the display area have a single gate structure. However, the pixel TFTs, as in the gate driver TFT, may have a dual-gate structure (multi-gate structure) which includes an intermediate electrode having a greater distance from the drain electrode than the distance from the source electrode. The pixel TFTs may have a dual-gate structure similar to a conventional one (a dual-gate structure including an intermediate electrode of which the distance from the source electrode and the distance from the drain electrode are the same). Also, a dual-gate structure may be adopted in which all of the gate driver TFTs provided in the gate driver circuit portion include an intermediate electrode having a greater distance from the drain electrode than a distance from the source electrode. Alternatively, some of the gate driver TFTs provided in the gate driver circuit portion (preferably, those having a high required drain breakdown voltage) may have a dual-gate structure including an intermediate electrode having a greater distance from the drain electrode than a distance from the source electrode, and the other gate driver TFTs (preferably, those having a low required drain breakdown voltage) may have a single gate structure or a dual-gate structure similar to a conventional one. Alternatively, the pixel TFTs may have a dual-gate structure including an intermediate electrode having a greater distance from the drain electrode than a distance from the source electrode, and all of the gate driver TFTs provided in the gate driver circuit portion may have a single gate structure or a dual-gate structure similar to a conventional one.

(23) In the foregoing embodiments, the configuration has been described in which the array substrate is provided with the gate driver circuit portion. However, a configuration may be adopted in which the array substrate is not provided with the gate driver circuit portion. In this case, a dual-gate structure is adopted in which the pixel TFTs configuring the pixels in the display area include an intermediate electrode having a greater distance from the drain electrode than a distance from the source electrode.

### EXPLANATION OF SYMBOLS

16, 116, 216: Gate insulating film (Insulating film)
17: Oxide semiconductor film (Semiconductor film)
19, 119, 219: Interlayer insulating film (Second insulating film)
22, 122, 322, 422, 522: Intermediate electrode
23, 223: Channel protection portion
24: Third metal film (Electrically conductive film)
25: Second gate electrode
26, 526: Opening portion
30, 130, 230, 330, 430, 530: Gate driver TFT (Thin-film transistor)
30a, 130a, 230a, 330a, 430a, 530a: Gate electrode
30b, 130b, 330b, 430b, 530b: Source electrode
30c, 130c, 330c, 430c, 530c: Drain electrode
30d, 130d, 230d, 330d: Channel portion
CH2: Contact hole
L1: Distance
L2: Distance

1. A thin film transistor comprising:
a gate electrode;
a channel portion overlapping the gate electrode with an insulating film disposed therebetween, the channel portion being constructed from a semiconductor film;
a source electrode connected to one end of the channel portion;
a drain electrode connected to another end of the channel portion; and
an intermediate electrode connected to the channel portion at a position at which a distance to the drain electrode is greater than a distance to the source electrode.

2. The thin film transistor according to claim 1, comprising a channel protection portion overlapping the channel portion, with a second insulating film disposed therebetween and lying over the channel portion on an opposite side from a gate electrode side, the channel protection portion being constructed from an electrically conductive film.

3. The thin film transistor according to claim 2, wherein the channel protection portion includes a second gate electrode to which a signal synchronized with a signal supplied to the gate electrode is supplied.

4. The thin film transistor according to claim 3, wherein the second gate electrode is connected to the gate electrode through contact holes formed in the insulating film and the second insulating film.

5. The thin film transistor according to claim 2, wherein the channel protection portion is disposed not to overlap the intermediate electrode and the drain electrode.

6. The thin film transistor according to claim 1, wherein the source electrode and the drain electrode are narrower than the channel portion.

7. The thin film transistor according to claim 6, wherein the intermediate electrode is wider than the source electrode and the drain electrode.

8. The thin film transistor according to claim 1, wherein the gate electrode includes an opening at a position to overlap the intermediate electrode.

9. The thin film transistor according to claim 1, wherein the semiconductor film is an oxide semiconductor film.
